(19) United States
(12) Patent Application Publication
(10) Pub. No.: US 2026/0301821 A1
(43) Pub. Date: Oct. 1, 2026

(54) FLASH MEMORY DEVICE WITH IMPROVED CHARGE RETENTION CHARACTERISTICS AND OPERATION METHOD THEREOF

(71) Applicants: SK hynix Inc., Icheon-si (KR); SEOUL NATIONAL UNIVERSITY R&DB FOUNDATION, Seoul (KR)

(72) Inventors: Sung Ho PARK, Seoul (KR); Jong Ho Lee, Seoul (KR)

(21) Appl. No.: 19/236,688

(22) Filed: Jun. 12, 2025

(30) Foreign Application Priority Data
Mar. 28, 2025 (KR) 10-2025-0040722

(51) Int. Cl. G11C 16/14; G11C 16/08; G11C 16/04

(52) U.S. Cl. CPC G11C 16/14; G11C 16/08; G11C 16/0483

(57) ABSTRACT

A flash memory device includes a cell array and a control circuit. The cell array includes a plurality of flash memory cells having control gates connected to a plurality of word lines, a drain selection switch controlled by a drain selection line and connected between the plurality of flash memory cells and a bit line, a source selection switch controlled by a plurality of source selection lines and connected between the plurality of flash memory cells and a source line and a spacer region disposed in a portion of a charge trap layer and located between memory cells. The control circuit is configured to control an electron injection operation to inject electrons from at least one of the plurality of word lines into a spacer region before performing a write operation to program a selected flash memory cell among the plurality of flash memory cells.

### CROSS-REFERENCE TO RELATED APPLICATION

The present application claims priority to Korean Patent Application No. 10-2025-0040722, filed on March 28, 2025, which is incorporated herein by reference in its entirety.

### BACKGROUND

Embodiments relate to a flash memory device with improved charge retention characteristics and an operation method thereof.

When a program operation of a flash memory device is performed, electrons are injected into a charge trap layer thereof.

The electrons injected into the charge trap layer diffuse to the surrounding region over time, which deteriorates the electron retention characteristics and consequently reduces the reliability of the flash memory device.

### SUMMARY

In accordance with an embodiment of the present disclosure, an operation method of a flash memory device comprising a NAND string including a plurality of flash memory cells having control gates connected to a plurality of word lines, a drain selection switch controlled by a drain selection line and connected between the plurality of flash memory cells and a bit line, and a source selection switch controlled by a plurality of source selection lines and connected between the plurality of flash memory cells and a source line, the operation method may include injecting electrons provided from at least one of the plurality of word lines into a spacer region ; and programming a selected flash memory cell among the plurality of flash memory cells, wherein the spacer region is included in a portion of a charge trap layer and the portion of the charge trap layer is located between the plurality of memory cells.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates a flash memory device according to an embodiment of the present disclosure.

FIG. 2 illustrates an operation of a flash memory device according to an embodiment of the present disclosure.

FIGS. 3A to 3C illustrate cross-sectional views of a flash memory device according to an embodiment of the present disclosure.

FIG. 4 is a timing diagram showing an electron injection operation of a flash memory device according to an embodiment of the present disclosure.

FIG. 5 illustrates an electron injection operation of a flash memory device according to an embodiment of the present disclosure.

FIG. 6 is a graph showing an electron injection operation of a flash memory device according to an embodiment of the present disclosure.

FIG. 7 illustrates movement of charges during an electron injection operation of a flash memory device according to an embodiment of the present disclosure.

FIG. 8 illustrates effect of an electron injection operation of a flash memory device according to an embodiment of the present disclosure.

FIG. 9 is a graph showing effect of a write operation of a flash memory device according to an embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

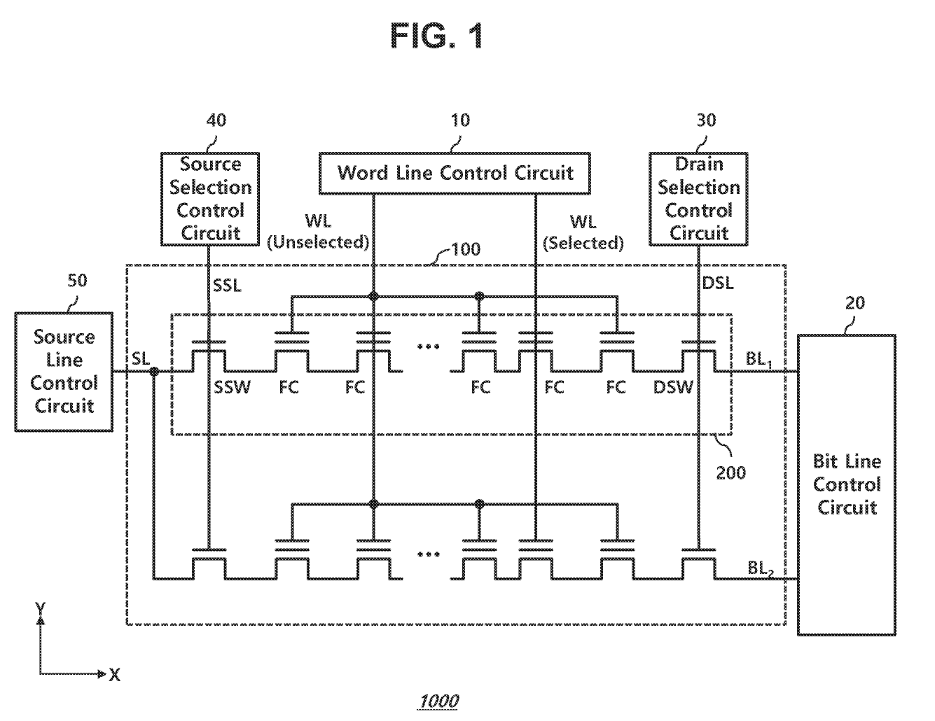

FIG. 1 is a block diagram showing a flash memory device 1000 according to an embodiment of the present disclosure.

The flash memory device 1000 includes a cell array 100 including a plurality of NAND strings 200, each NAND strings 200 including a respective plurality of flash memory cells FC, a word line control circuit 10 controlling a word line WL of the cell array 100, a bit line control circuit 20 controlling a bit line BL of the cell array 100, a drain selection control circuit 30 controlling a drain selection line DSL of the cell array 100, a source selection control circuit 40 controlling a source selection line SSL of the cell array 100, and a source line control circuit 50 controlling a source line SL of the cell array 100.

The word line control circuit 10, the bit line control circuit 20, the drain selection control circuit 30, the source selection control circuit 40, and the source line control circuit 50 may be collectively referred to as a control circuit.

That is, in this disclosure, the control circuit controls the word line WL, the bit line BL, the drain selection line DSL, the source selection line SSL, and the source line SL to control the overall operations such as a block erase operation, a program operation, etc. in the cell array 100.

In FIG. 1, the cell array 100 including two NAND strings 200 is illustrated as an example, but the cell array 100 may include a plurality of NAND strings 200 and the pluralities of flash memory cells FC may be arranged in two or three dimensions.

One word line is commonly connected to control gates of a plurality of flash memory cells aligned in the Y-axis direction.

In FIG. 1, the bit line BL is connected to a drain of the drain selection switch DSW of the corresponding NAND string 200.

One drain selection line DSL is commonly connected to gates of the drain selection switches of a plurality of NAND strings 200 aligned in the Y-axis direction.

The source line SL is commonly connected to sources of the source selection switches SSW of all NAND strings 200.

The source selection line SSL is commonly connected to the gates of the source selection switches SSW of all NAND strings 200.

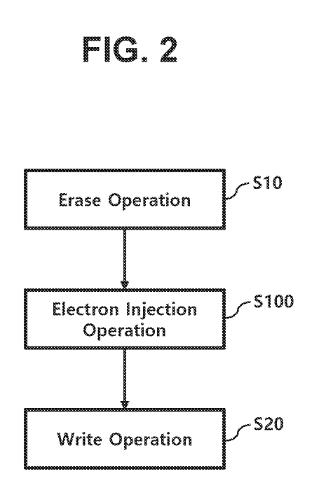

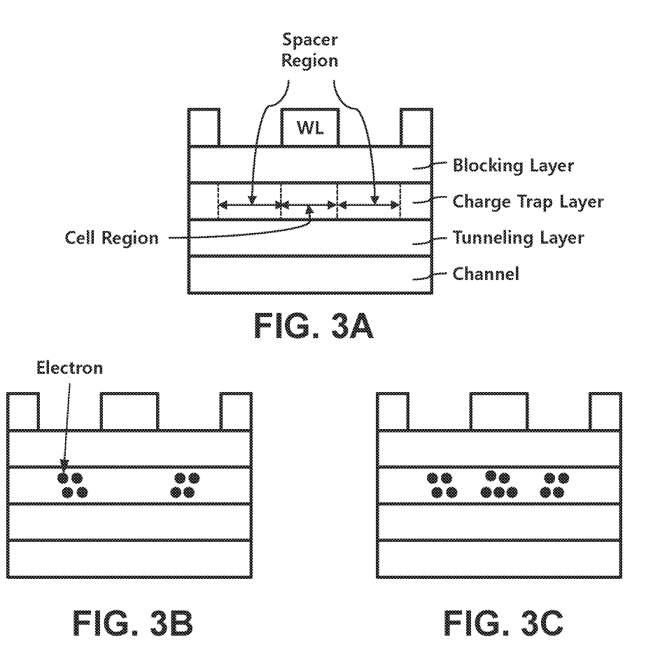

FIG. 2 is a flowchart showing an operation of a flash memory device according to an embodiment of the present disclosure, and FIGS. 3A to 3C are cross-sectional views of a flash memory cell.

In the present disclosure, an electron injection operation S100 is performed after performing an erase operation S10, and a write operation S20 is performed for a selected flash memory cell after the electron injection operation S100.

The erase operation S10 and the write operation S20 themselves are identical to the conventional erase operation and write operation.

FIG. 3A corresponds to a flash memory cell after the erase operation S10, FIG. 3B corresponds to a flash memory cell after the electron injection operation S100, and FIG. 3C corresponds to a flash memory cell after the write operation S20.

As is well known, a flash memory cell may have a structure in which a channel, a tunnel layer, a charge trap layer, a blocking layer, and a metal wiring layer having a plurality of word lines spaced apart are sequentially stacked as in FIG. 3A. The charge trap layer may be represented as an electron trap layer.

Hereinafter, a region of the charge trap layer below the word line is referred to as a cell region, and a region of the charge trap layer between cell regions is referred to as a spacer region.

In a conventional flash memory device, a write operation is performed on a page after initializing a block through an erase operation.

However in the present disclosure, after the erase operation S10, the electron injection operation S100 is performed to inject electrons into the spacer region of the charge trap layer using electron back tunneling (EBT) phenomenon, thereby improving retention characteristics of electrons injected by the write operation S20.

FIG. 3B shows a state in which electrons are injected into the spacer region through the electron injection operation S100, and FIG. 3C shows a state in which electrons are additionally injected into the cell region between the spacer regions through the write operation.

Due to the electrons present in the spacer region, the charge retention characteristics can be improved because the electrons in the cell region cannot diffuse to the surrounding spacer regions.

The electron injection operation S100 will be described in detail below.

In general, a flash memory device performs a write operation in units of word lines and an erase operation in units of blocks.

For example, one block corresponds to all flash memory cells included in a certain number of NAND strings 200 selectable by all of a predetermined plurality of word lines.

During an initialization process of a flash memory device, the entire block is erased and then an electron injection operation S100 is performed for each block.

During use of a flash memory device, a block is erased through a garbage collection operation and then an electron injection operation S100 is performed for the block. The electron injection operation S100 may be performed before any of the cells in the block are written to.

The operation of FIG. 2 for one NAND sting 200 may be explained as follows.

First, in the erase operation S10, all flash memory cells FC included in the NAND string 200 are erased.

Then, in the electron injection operation S100, electrons are injected into the spacer region of the charge trap layer below all flash memory cells included in the NAND string 200.

Then, a write operation S20 is performed for each flash memory cell FC included in the NAND string 200.

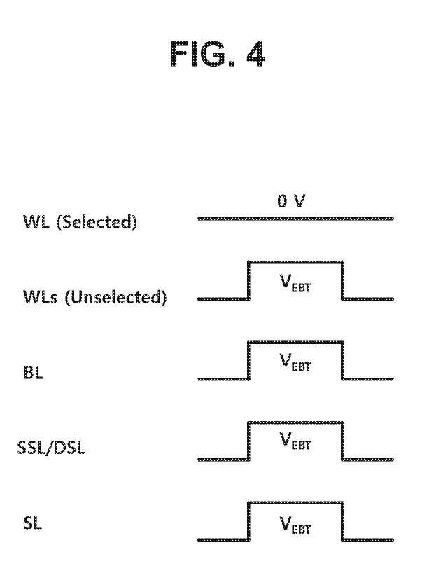

FIG. 4 is a timing diagram showing an electron injection operation according to an embodiment of the present disclosure.

In the present disclosure, electrons are injected into the spacer region using the EBT phenomenon.

Hereinafter, an electron injection operation for one NAND string 200 using the EBT phenomenon is disclosed.

First, a first voltage is applied to a selected word line.

In addition, a second voltage V_{EBT} is applied to unselected word lines comprising the word lines other than the selected word line, to the bit lines, to the drain selection lines, to the source selection lines, and to the source lines. At this time, the second voltage V_{EBT} may be referred to as an EBT voltage.

The second voltage is greater than the first voltage by a predetermined magnitude (for example, by 20 volts).

In this embodiment, the first voltage is 0V and the second voltage is a positive voltage having the predetermined magnitude, but in another embodiment, the second voltage may be 0V and the first voltage may be a negative voltage having the predetermined magnitude.

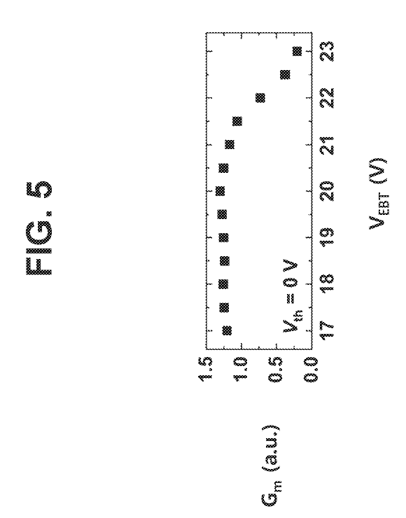

FIG. 5 is a graph explaining an electron injection operation of a flash memory device according to an embodiment of the present disclosure.

In the graph, when the second voltage exceeds 20V, the transconductance Gₘ of the channel layer decreases.

The decrease in the transconductance of the channel layer indicates that the channel resistance of the selected NAND string 200 increases, which is because electrons move from the selected word line to the charge trap layer by the electron injection operation.

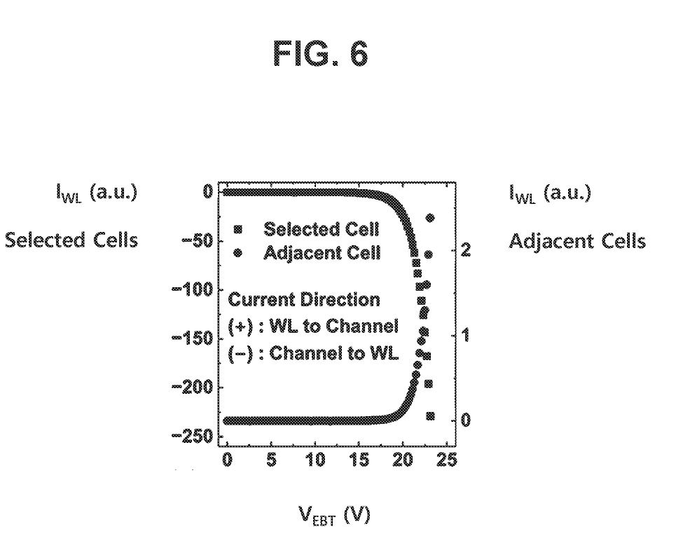

FIG. 6 is a graph showing currents during the electron injection operation.

The upper line and square marks indicates selected current flowing through the selected word line, and the lower line and circle marks indicates unselected current flowing through the word lines adjacent to the selected word line.

In FIG. 6, the selected current is indicated based on a scale on the left side, and the unselected current is indicated based on a scale on the right side.

When magnitude of the second voltage exceeds 20V, the magnitude of the selected current begins to increase rapidly due to the electrons provided from the selected word line. At this time, the magnitude of the unselected current also begins to increase.

This indicates that during the electron injection operation, most of the electrons provided from the selected word line spread out within the charge trap layer, and some flow toward the adjacent word lines.

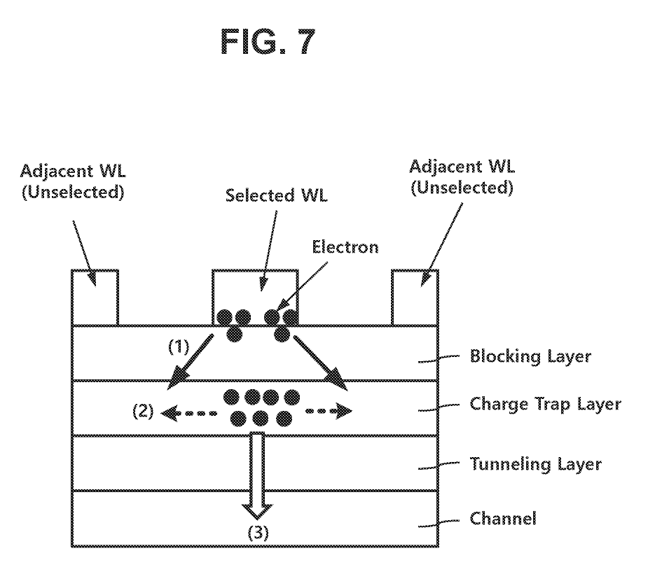

FIG. 7 is a diagram explaining the movement of electrons during the electron injection operation according to an embodiment of the present disclosure.

As shown in FIG. 4, when the first voltage and the second voltage are applied, electrons move from the selected word line to the spacer region of the charge trap layer by the Fowler-Nordheim (FN) EBT phenomenon. Hereinafter, this is referred to as a first movement.

Electrons existing in the cell region of the charge trap layer may also move to the spacer region by the Poole-Frankel (PF) emission phenomenon. Hereinafter, this is referred to as a second movement.

In addition, electrons existing in the cell region of the charge trap layer move from the cell region to the channel region by the FN tunneling phenomenon, which is referred to as a third movement below. The third movement is similar to the movement of electrons during an erase operation.

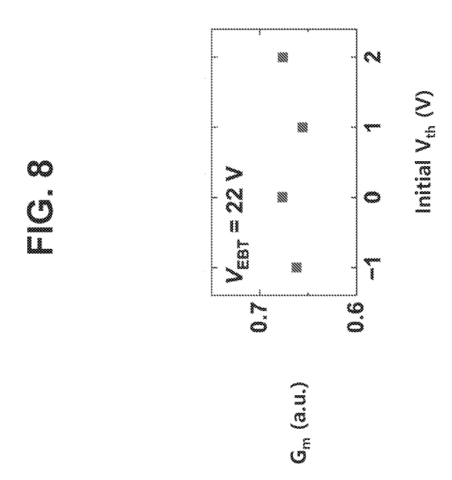

FIG. 8 is a graph showing an effect of an electron injection operation of a flash memory device according to an embodiment of the present disclosure.

FIG. 8 shows that the transconductance is substantially constant after the electron injection operation regardless of the initial value of the threshold voltage.

An initial value of the threshold voltage depends on amount of electrons existing in the cell region.

That is, regardless of the initial value of the threshold voltage, the fact that the transconductance remains constant after the electron injection operation indicates that the second movement of electrons mentioned in relation to FIG. 7 has little effect on the electron injection operation.

In the present disclosure, the electron injection operation is performed after the erase operation as shown in FIG. 2, and in this case, since there are no electrons in the cell region, the possibility of the second movement and the third movement is low.

In the present disclosure, the electron injection operation is performed after the erase operation as shown in FIG. 2, and in this case, there are almost no electrons in the cell region.

Even if there are some electrons in the charge trap layer before the electron injection operation despite the erase operation, it can be understood that they have little effect on the electron injection operation.

In the above, the electron injection operation was disclosed by referring to one selected word line and adjacent unselected word lines.

As aforementioned, when the electron injection operation is performed by selecting some word lines in the NAND string, electrons are injected into the spacer regions on both sides of the selected word line.

However, considering that the erase operation is performed in block units, the electron injection operation can be performed by selecting all word lines included in the NAND string.

In this case, electrons are accumulated in the spacer region between all word lines included in the NAND string through a single electron injection operation.

As disclosed in FIG. 7, an erase phenomenon like the third movement can occur when the electron injection operation is performed by using the EBT phenomenon.

If the electron injection operation is performed by selecting all word lines of the NAND string, the erase operation of FIG. 2 can be omitted.

However, when the electron injection operation is repeatedly performed without the erase operation, the amount of electrons accumulated in the spacer region can vary depending on the number of electron injection operations, and in this case, the characteristics of the flash memory cell may not be maintained consistently depending on the NAND strings.

Therefore, in order to maintain the characteristics of the flash memory cell consistently, it is desirable to perform the erase operation before the electron injection operation to remove electrons from the charge trap layer.

However, if the characteristics of the flash memory cell are maintained consistently within a predetermined range that satisfies a predetermined condition, an embodiment in which the erase operation is omitted and only the electron injection operation is performed is also possible.

For example, an erase operation can be omitted for every two electron injection operations. That is, an erase operation corresponding to a second electron injection operation per two electron injection operations can be omitted.

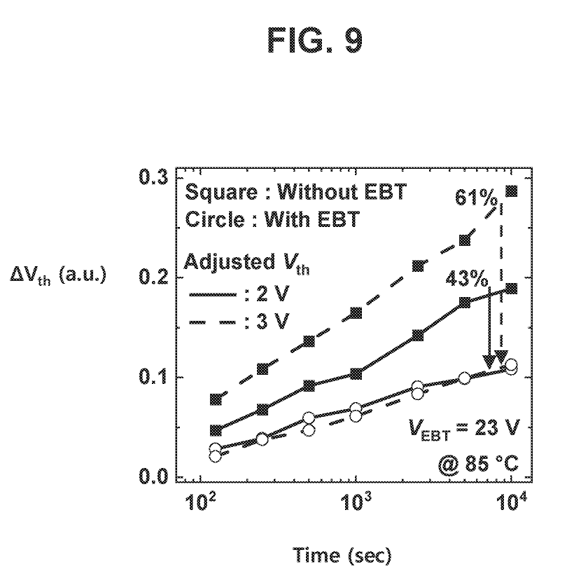

FIG. 9 is a graph showing change in threshold voltage over time.

In FIG. 9, the solid mark corresponds to a case in which the electron injection operation is not performed, and the open mark corresponds to a case in which the electron injection operation is performed.

Also, a dashed line corresponds to a case in which the initial threshold voltage is 3V, and a solid line corresponds to a case in which the initial threshold voltage is 2V.

If performance improvement is measured based on threshold voltage fluctuation when 10,000 secs have elapsed after a write operation, a 43 percent performance improvement was observed when the initial threshold voltage was 2V, and a 61 percent performance improvement was observed when the initial threshold voltage was 3V.

Although some embodiments have been described above for illustrative purposes, various changes and modifications may be made to the above-described embodiments.

What is claimed is:

1. A flash memory device comprising:
a cell array including a plurality of flash memory cells having control gates connected to a plurality of word lines, a drain selection switch controlled by a drain selection line and connected between the plurality of flash memory cells and a bit line, and a source selection switch controlled by a plurality of source selection lines and connected between the plurality of flash memory cells and a source line; and
a control circuit configured to control an electron injection operation to inject electrons from at least one of the plurality of word lines into a spacer region,
wherein the electron injection operation is performed before performing a write operation to program a selected flash memory cell among the plurality of flash memory cells, and
wherein the spacer region is included in a portion of a charge trap layer and the portion of the charge trap layer is located between memory cells.

2. The flash memory device of claim 1, wherein the control circuit controls performing an erase operation to erase the plurality of flash memory cells before performing the electron injection operation.

3. The flash memory device of claim 2, wherein the control circuit controls so that the electron injection operation be performed at least one time after a block including the NAND string is erased and before the block is erased again.

4. The flash memory device of claim 1, wherein the control circuit controls voltages of the plurality of word lines, the bit line, the source line, the drain selection line, and the source selection line so that electrons move from the plurality of word lines to the spacer region during the charge injection operation.

5. The flash memory device of claim 4, wherein the control circuit sets voltages of the plurality of word lines to be a first voltage and sets voltages of bit line, the source line, the drain selection line, and the source selection line to be a second voltage greater than the first voltage.

6. The flash memory device of claim 1, wherein the control circuit controls voltages of the plurality of word lines, the bit line, the source line, the drain selection line, and the source selection line so that electrons move from a selected word line connected to the selected flash memory cell among the plurality of word lines to the spacer region during the charge injection operation.

7. The flash memory device of claim 6, wherein the control circuit sets voltage of the selected word line to be a first voltage and sets voltages of word lines other than the selected word lines among the plurality of word lines, the bit line, the source line, the drain selection line, and the source selection line to be a second voltage greater than the first voltage.

8. An operation method of a flash memory device comprising a NAND string including a plurality of flash memory cells having control gates connected to a plurality of word lines, a drain selection switch controlled by a drain selection line and connected between the plurality of flash memory cells and a bit line, and a source selection switch controlled by a plurality of source selection lines and connected between the plurality of flash memory cells and a source line, the operation method comprising:
injecting electrons provided from at least one of the plurality of word lines into a spacer region; and
programming a selected flash memory cell among the plurality of flash memory cells
wherein the spacer region is included in a portion of a charge trap layer and the portion of the charge trap layer is located between the plurality of memory cells.

9. The operation method of claim 8, further comprising erasing the plurality of flash memory cells before injecting the electrons.

10. The operation method of claim 9, wherein injecting the electrons is performed at least once after a block including the NAND string is erased and before the block is erased again.

11. The operation method of claim 8, wherein voltages of the plurality of word lines, the bit line, the source line, the drain selection line, and the source selection line are set so that electrons move from the plurality of word lines to the spacer region while injecting the electrons.

12. The operation method of claim 11, wherein voltages of the plurality of word lines are set to be a first voltage and voltages of bit line, the source line, the drain selection line, and the source selection line are set to be a second voltage greater than the first voltage while injecting the electrons.

13. The operation method of claim 8, wherein voltages of the plurality of word lines, the bit line, the source line, the drain selection line, and the source selection line are set so that electrons move from a selected word line connected to the selected flash memory cell among the plurality of word lines to the spacer region while injecting the electrons.

14. The operation method of claim 13, wherein voltage of the selected word line is set to be a first voltage and voltages of word lines other than the selected word line among the plurality of word lines, the bit line, the source line, the drain selection line, and the source selection line are set to be a second voltage greater than the first voltage.
